(19) United States
(12) Patent Application Publication
(10) Pub. No.: US 2004/0017274 A1
(43) Pub. Date: Jan. 29, 2004

(54) Rotary electromagnet

(76) Inventors: Nicolas Hertzog, Rueil-Malmaison (FR); Pascal Machon, Colombes (FR); Franck Declomesnil, Paris (FR)

Correspondence Address: Parkhurst & Wendel, 1421 Prince Street Suite 210, Alexandria, VA, 22314-2805, US

(21) Appl. No.: 10/258,346

(22) PCT Filed: Apr. 26, 2001
(86) PCT No.: PCT/FR01/01300

(30) Foreign Application Priority Data
May 2, 2000 (FR) 00/05739

(51) Int. Cl. H03K 3/00

(52) U.S. Cl. 335/132

(57) ABSTRACT

The invention concerns an electromagnetic device of a switching apparatus comprising a mobile armature (20) rotating in a fixed frame (10) between two inactive and active positions, at least a permanent magnet (15, 15′) mounted in the fixed frame, at least a coil (24, 25) mounted in the mobile armature and control means (40) capable of delivering a control current (44) into the coil. The mobile armature is monostable; in inactive position, a lever (30) actuated by the mobile armature brings about the separation between the fixed contacts (31) and the mobile contacts (32) of the apparatus. In active position, the lever is released from the mobile armature and a spring (35) presses the mobile contact on the fixed contacts.

This invention relates to an electromagnetic control device for opening and closing contacts, comprised of a movable armature rotating between two stops. Said device is particularly suited for use in a low voltage power switch such as a contactor or contactor/breaker.

An electromagnetic control device comprising a mobile armature rotating between two positions formed by two stops arranged in a fixed frame and comprising at least one permanent magnet and at least one coil on a fixed frame (see patent application N^{o} FR9906592). The permanent magnet serves to maintain the mobile armature in a given position when the coil is not creating a magnetic field. Said device is bistable and, in order to switch the mobile armature from one position to another, it is necessary to circulate a current in the coil either in one direction or in the other or, if using two opposed coils, in such a fashion as to create a magnetic field, in one direction or in another, greater than that generated by the permanent magnet. Consumption by such a device is thus significant. In other respects, DE3005921 discloses a monostable electromagnetic control device, in which at least one magnet is counted on a mobile armature and a coil is mounted on the fixed frame. But the fact of mounting the coil or coils in the fixed frame involves an undesirable increase of the size of the entire device.

On the other hand, U.S. Pat. No. 5029618 discloses an electromagnetic control applied to a mechanism for textile machinery. Said device is either rotary and bistable or linear and monostable in virtue of an asymmetry of the air gap of the two magnets comprising it. Therefore, the power of the one device is not adapted for efficiently opening and closing the power contacts of a switching apparatus such as is desired in the invention.

The object of the present invention is to provide the simplest possible electromagnetic control device for a switching apparatus capable of responding to extreme constraints of space requirements and consumption.

In order to achieve this, the invention describes an electromagnetic control device for opening and closing contacts of a switching apparatus comprising:

a monostable mobile armature that is mobile in rotating about an axis of rotation within a fixed frame between two stops delimiting a inactive position and an active position, respectively, and which mechanically cooperates with an actuation lever for the contacts, the mobile armature comprising an elongated core along a longitudinal axis running perpendicular to the axis of rotation and having two convex opposing ends.

at least one permanent magnet mounted in the fixed frame along an axis of magnetization passing through the axis of rotation and having a polar surface that is substantially concave in shape with respect to at least one end of the mobile armature;

at least one coil mounted on the mobile armature;

control means capable of delivering a control current into said coil(s).

In the presence of a control current in the coil of a value of zero or less than the threshold of activation, the mobile armature switches to a first of the aforesaid two positions (inactive and active, respectively) by virtue of the force of attraction of the permanent magnet (s). In the presence of a command current of a value greater than the threshold of activation greater than or equal to the threshold of activation, the mobile armature switches to the second of the aforesaid two positions (inactive and active, respectively) by virtue of the force of repulsion of the permanent magnet(s).

According to one characteristic, the fixed frame comprises two permanent magnets that are positioned symmetrically relative to the axis of rotation of the mobile armature and which each have a polar surface that is substantially concave cooperating with one opposed convex end of the mobile armature in such a fashion as to minimize the forces necessary to the switching movements of the mobile armature. The longitudinal axis of the core of the mobile armature is always displaced on the same side relative to the axis of magnetization of the two permanent magnets.

The coil(s) is (are) mounted on the mobile armature by means of a cage or housing that encloses the core and which exhibits transverse clamps or rings at least one of which cooperating with an interior surface of the fixed frame.

According to another characteristic, the control means comprises an electronic circuit capable of receiving an input of an opening instruction and a closing instruction and delivering to the output a control current into the coil(s) (24, 25).

A further object of the invention is a switching apparatus equipped with one such electromagnetic control device.

Other advantages and characteristics of the invention issue from the following detailed description read together with the annexed drawings, in which :

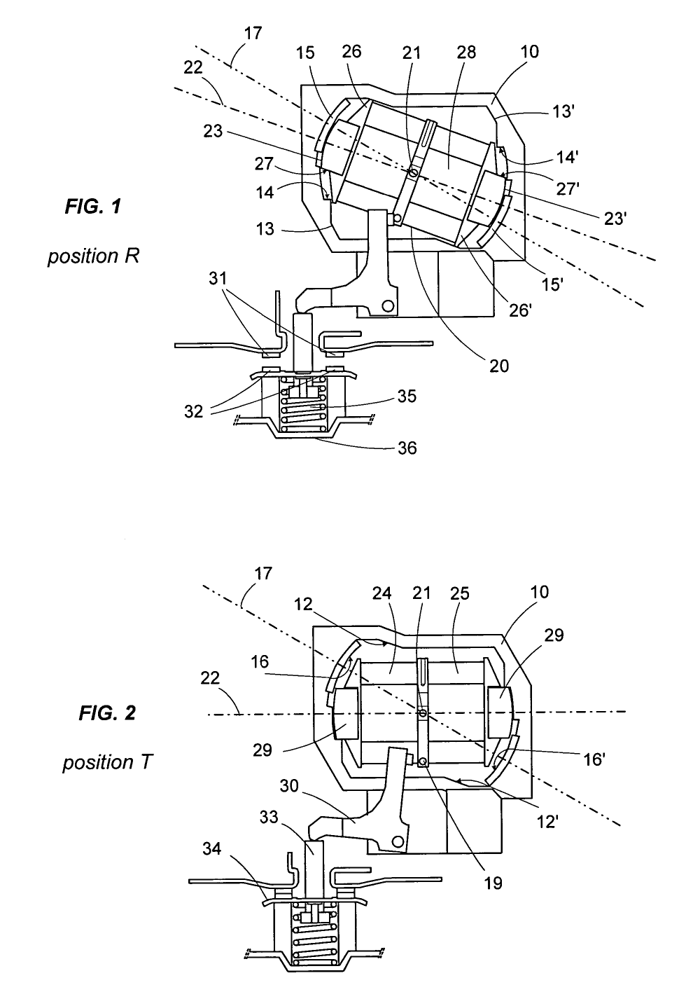

FIG. 1 represents an embodiment of an electromagnetic control device for opening and closing contacts in its inactive position;

FIG. 2 represents the same electromagnetic control device in its active position;

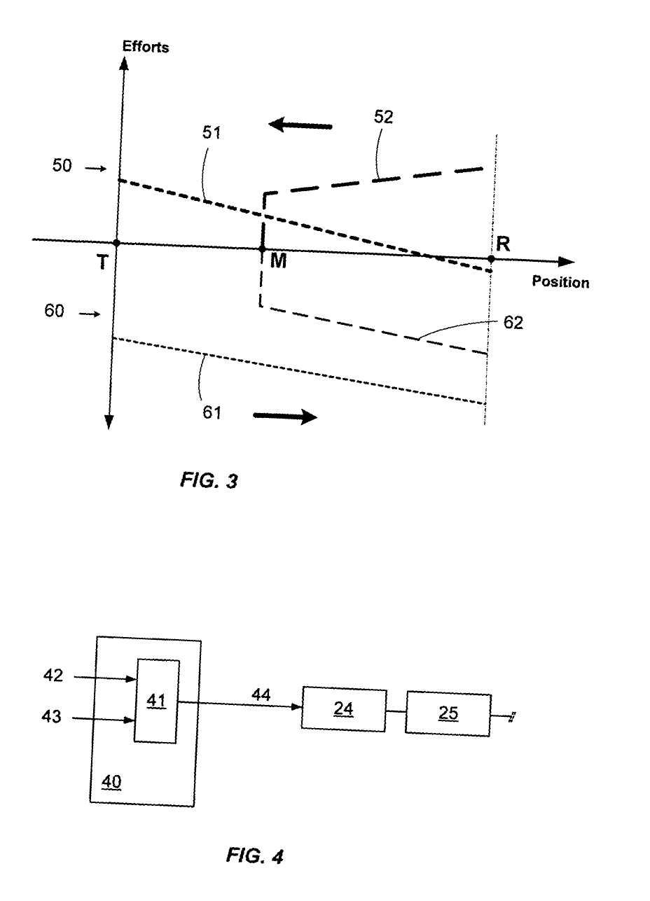

FIG. 3 illustrates the course of the different force curves acting upon the mobile armature of the device;

FIG. 4 details the control means of the device.

The electromagnetic control device is intended for opening and closing of the contacts of a switching apparatus. According to the embodiment represented in FIG. 1 it comprises a metal fixed frame 10, indentations on the inside of which a mobile armature 20 is situated between two stops arranged on the fixed frame 10 delimiting an inactive R position and an active T position, about an axis of rotation 21 perpendicular to a longitudinal axis 22 of the mobile armature 20. A first stop, delimiting the inactive R position, is made up of two initial inside surfaces 12, 12′ of the fixed frame 10, symmetrical relative to the axis of rotation 21. A second stop, delimiting the active T position, is made up of two second inside surfaces 13, 13′ of the fixed frame, symmetrical relative to the axis of rotation 21. The mobile armature 20 is comprised of an elongated metal core 29 along the longitudinal axis 22 exhibiting two opposed convex ends 23, 23′ mounted symmetrically about its axis of rotation 21.

The mobile armature 20 cooperates mechanically with a actuation lever 30 for the contacts of the switching apparatus by means of a pin 19 mounted on the mobile armature 20 in such a fashion that in the inactive position R the mobile armature 20 controls the separation between the mobile contacts 32 and the fixed contacts 31 of the switching apparatus. In the inactive R position, this control is transmitted by the pin 19 which operates the lever 30, itself entraining by pivoting an attached pusher 33 of a contact holder 34 supporting the mobile contacts 32 (see FIG. 1). When the mobile armature 20 is in the active T position, the pin 19 is separated from the lever 20 (see FIG. 2). The application of the mobile contacts 32 on the fixed contacts 31 of the switching apparatus is thus assured by a contact compression spring 35 that bears upon the contact holder 34 and upon a fixed support 36 of the switching apparatus.

With reference to FIG. 1, the mobile armature 20 has a cage or housing 28 surrounding the metal core 29 and on which at least one coil is arranged. In a preferred fashion, two coils 24, 25 mounted electrically in series are arranged on either end of the axis of rotation 21 along the longitudinal axis 22 of the mobile armature 20. The cage 28 of the coils additionally has at its ends several transverse rings 26, 26′. The limitation of the movements of the mobile armature 20 is obtained:

by means of one of the rings 26, 26′ which cooperates with a stop formed by at least one of the two first inside surfaces 12, 12′ of the fixed frame 10, thus delimiting the inactive R position;

by the core 29 one of whose lateral surfaces 27, 27′ cooperates with a stop formed by at least one of the two flanges 14, 14′ of the fixed frame 10, thus delimiting the active T position.

This type of assembly allows significant reduction of the total space requirement of the device by not necessitating placement for the coils 24, 25 on the fixed frame 10.

At least one permanent magnet 15, 15′ is fixed inside the fixed frame 10. Advantageously, the fixed frame 10 comprises on its inside part two permanent magnets 15 (15′, respectively) positioned symmetrically relative to the axis of rotation 21 of the mobile armature 20 and each having one polar surface 16 (16′, respectively) that is substantially concave and positioned with respect to a same convex extremity 23 (23′, respectively) of the mobile armature 20. The substantially concave form of the polar surfaces 16, 16′ and the convex shape of the ends 23, 23′ are particularly adapted so that these polar surfaces 16, 16′ cooperate with these ends 23, 23′ in such fashion as to minimize the dimension of the air gap created between the magnets 15, 15′ and the core 29 in such fashion as to minimize the variations of said air gab during the movements of the mobile armature 20. This thus allows reduction of the forces necessary to the switching movements of the mobile armature 20.

As shown in FIGS. 1 and 2, the two magnets 15, 15′ are magnetized along substantially the same axis of magnetization 17. The direction of magnetization of the two magnets 15, 15′ is opposed by one relative to the other; that is, the pole of the polar surface 16 is the reverse of the pole of the polar surface 16′. The axis of magnetization 17 passes through the axis of rotation 21 of the mobile armature 20 and is perpendicular to the axis of rotation 21. The advantage of having the polar surfaces of the magnets that cooperate with the ends of the mobile armature allows giving the maximum amplitude to the attraction/repulsion forces of the magnets of the mobile armature.

The device according to the invention is constructed in such a fashion that the longitudinal axis 22 of the core 29 of the mobile armature 20 crosses the axis of magnetization 17 of the permanent magnets substantially at the level of the axis of rotation 21. Moreover, the longitudinal axis 22 is displaced from the same side relative to the axis of magnetization 17, regardless of the position of the mobile armature 20, whether in the inactive R position or the active T position, with an angle greater than 0° and less than 60°.

With reference to FIG. 4, the electromagnetic control device comprises also control means 40 capable of delivering a control current 44 to the coils 24, 25. The control means 40 comprise an electronics circuit 41 that can receive at entry a closing instruction 42 and an opening instruction 43 and which, as a function of these inputs, delivers at the output the control current 44 into the coils 24, 25 of the mobile armature 20.

The operation of the present electromagnetic control device will now be described.

When an opening instruction 43 is received by the electronics circuit 41, the latter delivers into the coils 24, 25 a control current 44 of a zero value or less than an opening threshold D memorized in the electronics circuit 41. This opening threshold D is calculated such that the induced magnetic field B that results in the coils 24, 25 is sufficiently lower than the magnetic field M of the permanent magnets so that the metal core 29 of the mobile armature 20 is attracted by the permanent magnets 15, 15′ and switches towards a first of two positions, to the inactive R position, for example. As the longitudinal axis 22 of the core 29 is always displaced from the same side relative to the axis of magnetization 17 of the permanent magnets, this means that, even when the mobile armature has reached the R position, the permanent magnets 15, 15′ continue to exercise in the same direction an attraction force 61 on the mobile armature 20, thus allowing it to be firmly held in the inactive position R.

When a closing instruction 42 is received by the electronics circuit 41, it delivers to the coils 24, 25 a control current 44 of a value greater than a closing threshold E memorized in the electronics circuit 41. This closing threshold E is greater than the opening threshold D and is calculated such that the induced magnetic field B that results in the coils is sufficiently greater than the magnetic field M of the permanent magnets 15, 15′ that the mobile armature 20 is repelled by the magnets 15, 15′ and switched towards the second of the two positions, the active position T, for example. When the mobile armature 20 is in the T position, the two lateral faces 27, 27′ of the core 29 of the mobile armature are in contact with the flanges 14, 14′ of the fixed metal frame 10, which limits the movement and also permits the electromagnetic flux generated by the coils to loop back between the metal core 29 and the fixed frame 10 in such a fashion as to assure effective holding in the T position.

Switching over from the active T position to the inactive R position does not consume current, since it is due only to the force of attraction of the permanent magnets 15, 15′ on the mobile armature 20. Reciprocally, as there is no return spring to maintain the mobile armature 20 in this R position; thus, a low control current level 44 in the coils 24, 25 is sufficient to switch from the R position to the T position, thus entailing globally a very low consumption for the entire device. Likewise, the force necessary to bring the mobile contacts 32 up against the fixed contacts 31 does not consume any more current because it is assured by the spring 35.

Thus, given that the electromagnetic control device according to the invention never passes through an equilibrium position, since the longitudinal axis 22 of the core 29 is always offset from the same side relative to the axis of magnetism 17 of the permanent magnets and given that the low values of air gap and variations of air gap during the movements of the mobile armature 20, the result of which is that the attraction/repulsion forces associated with the permanent magnets are almost linear over the entire course of the mobile armature 20 and thus the R and T positions are very stable positions. In this fashion, high efficacy is achieved permitting the device to rapidly bring up and separate the mobile contacts 32 and the fixed contacts 31 of a power switching apparatus, even for higher electrical intensities.

FIG. 3 illustrates what would be the course of the different force curves acting upon the mobile armature 20 of the device according to the invention. In this illustration, the axis of the abscissas represents the course of the mobile armature between the active T position and the inactive R position. The portion above 50 of the graphic represents the forces at the time of movement of the mobile armature 20 from the R position towards the T position. The portion below 60 of the graphic represents the forces at the time of movement of the mobile armature 20 from the T position towards the R position.

Between the T position and a medial M position situated between T and R, the actuation lever 30 is dissociated from the mobile armature 20. Between the M position and the R position, the lever 30 is mechanically entrained by the pin 19 of the mobile armature 20 in order to separate the mobile contacts 32 form the fixed contacts 31 of the switching apparatus. The forces associated with the permanent magnets 15, 15′ are represented by the curves 51 and 61. The forces associated with the contact compression spring 35 are represented by the curves 52 and 62, these forces being present only between the M position and the R position of the mobile armature.

In the part below 60, the coils 24, 25 are traversed by a current 44 of zero value or less than the opening threshold D. Thus the force of attraction of the permanent magnets 15, 15′ generates a motive force on the mobile armature, represented by the curve 61; this force causing the mobile armature to pass from the T position in the direction of the R position. The force 61 must be greater than the repelling force represented on the curve 62. This repelling force 62 corresponds to the compression of the contact pressure spring 35 opposing the force of attraction of the permanent magnets between the M position and the R position; that is, when the actuation lever 30 engages the mobile contacts 32 of the switching apparatus.

In the part over 50, the coils 24, 25 are traversed by a current 44 with a value greater than the closing threshold E. The motive force associated with the permanent magnets 15, 15′ is thus reversed and from this point on entrains the mobile armature 20 from the R position towards the T position, as indicated in the curve 51. The force represented by the curve 52 that is generated by the contact compression spring 35 between the R position and the M position becomes from this point on a motive force that is additive to the motive force 51 facilitating the passage from the R position to the T position. It is noted that this motive force 51 on the mobile armature has no need to be significant because between the R position and the M position it is assisted by the force 52 from the contact compression spring 35 and, after the M position, as the actuation lever 30 no longer mechanically engages the mobile contacts of the switching apparatus, the motive force 51 must only just engage and then maintain the mobile armature weakly in the T position without encountering a repelling force. This has as its effect the low consumption by the electromagnetic control device, while lowering the closing threshold E of the current 44 into the coils 25, 25.

It is obvious that variations and enhancements of the detail and even envisaging of the use of equivalent means can be inspired without departing from the context of the invention.

1. An electromagnetic control device for opening and closing of the contacts of a switching apparatus, comprising:
a monostable mobile armature (20) that is mobile in rotation about an axis of rotation (21) in a fixed frame (10) between two stops delimiting, respectively, an inactive (R) position and an active (T) position and which cooperates mechanically with a contacts actuation lever (30), the mobile armature comprising a core (29) elongated along a longitudinal axis (22) perpendicular to the axis of rotation (21) and having two opposing concave ends (23, 23′);
at least one permanent magnet (15, 15′) mounted inside the fixed frame (10) along an axis of magnetization (17) passing through the axis of rotation (21) and having a polar surface that is substantially concave (16, 16′) relative to one end (23, 23′) of the mobile armature (20);
at least one coil (24, 25) on the mobile armature (20);
control means (40) capable of delivering a control current (44) into the coil(s) (24, 25).

2. A control device according to claim 1, wherein in the presence of a control current (44) of a value of zero or less than an opening threshold (D), the mobile armature (20) switches towards a first of the two aforesaid positions—inactive (R) and active (T), respectively—in virtue of the force of attraction of the permanent magnet(s) (15, 15′) and in the presence of a control current (44) of a value greater than a closing threshold (E) greater than or equal to the opening threshold (D), the mobile armature (20) switches towards the second of the two aforesaid positions—active (T) or inactive (R), respectively—in virtue of the force of repulsion of the permanent magnet(s) (15, 15′).

3. A control device according to claim 2, wherein the fixed frame (10) comprises two permanent magnets (15, 15′) along essentially one same axis of magnetization (17), positioned symmetrically relative to the axis of rotation (21) of the mobile armature (20) and each having a polar surface (16, 16′) of an essentially concave shape, cooperating with an opposing convex end (23, 23′) of the mobile armature (20) so as to minimize the value of the air gap created between the magnets (15, 15′) and the mobile armature (20) and so as to minimize the variations of said air gap during the movements of the mobile armature (20).

4. A control device according to claim 3, wherein, regardless of the position of the mobile armature (20), the longitudinal axis (22) of the core (29) of the mobile armature (20) is always shifted from the same side relative to the axis of magnetization (17) of the two permanent magnets (15, 15′).

5. A control device according to claim 4, wherein the coil(s) (24, 25) is (are) mounted on the mobile armature (20) by means of a cage (28) that surrounds the core (29) and which has transverse rings (26, 26′) at least one of with cooperates with one inside surface (12, 12′) of the fixed frame (10).

6. A control device according to claim 5, wherein, in the active (T) position, two lateral faces (27, 27′) of the core (29) of the mobile armature (20) are in contact with two flanges (14, 14′) of the fixed metal frame (10) so as to allow the electromagnetic flux generated by the coil(s) (24, 25) to loop back between the metal core (29) and the fixed frame (10).

7. A control device according to any one of the aforesaid claims, wherein the device comprises two coils (24, 25) that are arranged on the mobile armature (20) on both sides of the axis of rotation (21) of the mobile armature (20) and which are electrically mounted in series.

8. A control device according to any one of the aforesaid claims, wherein the control means (40) comprise an electronics circuit (41) capable of receiving at entry an opening instruction (43) and a closing instruction (42) and of delivering at output a control current (44) into the coil(s) (24, 25).

9. A control device according to claim 8, wherein, when a closing instruction (42) is received by the electronics circuit (41), said circuit delivers at the output a control current (44) of a value greater than the closing threshold (E), being sufficient to allow switching of the mobile armature (20) into the active (T) position.

10. A control device according to claim 8, wherein, when an opening instruction (43) is received by the electronics circuit (41), said circuit delivers at output a control current (44) of a value zero or less than the opening threshold (D), being sufficient to allow switching of the mobile armature (2) into the inactive (R) position.

11. A control device according to any one of the aforesaid claims, wherein, when the mobile armature (20) is in the inactive (R) position, the contacts actuation lever (30) mechanically entrains the separation between the mobile contacts (32) and the fixed contacts (31) of the switching apparatus.

12. A control device according to claim 11, wherein, when the mobile armature (20) is in the active (T) position, the contacts actuation lever (30) is mechanically dissociated from the mobile contacts (32) of the switching apparatus and a contact compression spring (35) urges the mobile contacts (32) against the fixed contacts (31) of the switching apparatus.

13. A switching apparatus, characterized in that it is equipped with a control device according to any one of the aforesaid claims.
